(19) United States
(12) Patent Application Publication
(10) Pub. No.: US 2012/0276743 A1
(43) Pub. Date: Nov. 1, 2012

(54) METHODS OF FORMING A CARBON TYPE HARD MASK LAYER USING INDUCED COUPLED PLASMA AND METHODS OF FORMING PATTERNS USING THE SAME

(76) Inventors: Jai-Hyung Won, Seoul (KR); Se-Jun Park, Seoul (KR)

(21) Appl. No.: 13/456,312

(22) Filed: Apr. 26, 2012

(30) Foreign Application Priority Data
Apr. 26, 2011 (KR) 10-2011-0039017
Jan. 3, 2012 (KR) 10-2012-0000744

(51) Int. Cl. H01L 21/311; H01L 21/314

(52) U.S. Cl. 438/694; 438/778; 257/E21.257; 257/E21.27

(57) ABSTRACT

A method of forming a carbon type hard mask layer using induced coupled plasma includes loading a substrate onto a lower electrode in a process chamber of an induced coupled plasma (ICP) deposition apparatus, the process chamber including an upper electrode and the lower electrode therein, generating a plasma in the process chamber, injecting a reactive gas into the process chamber such that the reactive gas is activated by colliding with the plasma, the reactive gas including a hydrocarbon compound gas, and applying a bias power to the lower electrode to form a diamond-like carbon layer on the substrate from the activated reactive gas.

### CROSS-REFERENCE TO RELATED APPLICATIONS

This application claims priority under 35 USC §119 to Korean Patent Application No. 2011-0039017, filed on Apr. 26, 2011, and Korean Patent Application No. 2012-0000744, filed on Jan. 3, 2012, in the Korean Intellectual Property Office (KIPO), the contents of which are incorporated by reference herein in their entirety.

### BACKGROUND

Example embodiments relate to methods of forming a hard mask layer. A hard mask layer may be used as an etching mask in forming semiconductor devices.

### SUMMARY

According to example embodiments, there is provided a method of forming a carbon type hard mask layer using induced coupled plasma, the method including loading a substrate onto a lower electrode in a process chamber of an induced coupled plasma (ICP) deposition apparatus, the process chamber including an upper electrode and the lower electrode therein, generating a plasma in the process chamber, injecting a reactive gas into the process chamber such that the reactive gas is activated by colliding with the plasma, the reactive gas including a hydrocarbon compound gas, and applying a bias power to the lower electrode to form a diamond-like carbon layer on the substrate from the activated reactive gas.

The bias power applied to the lower electrode may be from about 500 W to about 2000 W. The bias power applied to the lower electrode may be from about 900 W to about 1100 W.

The hydrocarbon compound gas may include at least one of C₃H₆, C₄H₈ and C₆H₁₂.

The diamond-like carbon layer formed on the substrate may have an absorption coefficient in a range of from about 0.05 to about 0.09. The diamond-like carbon layer formed on the substrate may have a carbon density in a range of from about 1.4 g/cc to about 1.7 g/cc.

The substrate may be maintained at a temperature of from about 75° C. to about 300° C.

The reactive gas further may include a boron-containing gas. The boron-containing gas may include at least one of borane (BH₃), diborane (B₂H₆) and boron trifluoride (BF₃). The reactive gas may further include hydrogen gas.

The ICP deposition apparatus may further include a gas supply providing the reactive gas and a process gas for generating the plasma. The gas supply may include a top nozzle and a side nozzle disposed at an upper wall and a sidewall of the process chamber, respectively. The reactive gas may be provided into the process chamber through the top nozzle at a flow rate of about 5 sccm to about 15 sccm and through the side nozzle at a flow rate of about 160 sccm to about 200 sccm.

The reactive gas may further include a boron-containing gas. The boron-containing gas may be provided into the process chamber through the side nozzle at a flow rate of about 10 sccm to about 70 sccm.

According to an embodiment, there is provided a method of forming a pattern, the method including loading a substrate having an insulation layer thereon onto a lower electrode in a process chamber of an induced coupled plasma (ICP) deposition apparatus, generating a plasma in the process chamber, injecting a reactive gas into the process chamber such that the reactive gas is activated by colliding with the plasma, the reactive gas including a hydrocarbon compound gas, applying a bias power to the lower electrode to form a hard mask layer on the insulation layer from the activated reactive gas, the hard mask layer including a diamond-like carbon, etching the hard mask layer to form a hard mask layer pattern, and etching the insulation layer to form an insulation layer pattern using the hard mask layer pattern as an etching mask. The reactive gas may further include a boron-containing gas.

According to an embodiment, there is provided a method of patterning one or more etching-subject layers stacked on a substrate, the method including loading a substrate having the one or more etching-subject layers stacked thereon onto a lower electrode in a process chamber of an induced coupled plasma (ICP) deposition apparatus; generating a plasma in the process chamber; injecting a reactive gas into the process chamber such that the reactive gas is activated by colliding with the plasma, the reactive gas including a hydrocarbon compound gas and a boron-containing compound; applying a bias power to the lower electrode to form a hard mask layer on the exposed surfaces of the one or more etching-subject layers, thereby forming a hard mask layer including a diamond-like carbon layer on the exposed surfaces of the one or more etching-subject layers; etching the hard mask layer to form a hard mask layer pattern; and patterning the one or more etching-subject layers by etching, using the hard mask layer pattern as an etching mask. The reactive gas may further include hydrogen gas.

The bias power may be applied to the electrode in a range of about 500 W to about 2000 W, and the substrate is maintained at a temperature of from about 75° C. to about 300° C. during the forming of the hard mask layer.

The ICP deposition apparatus may further include a gas supply providing the reactive gas and a process gas for generating the plasma, and the gas supply includes a top nozzle and a side nozzle disposed at an upper wall and a sidewall of the process chamber, respectively, the hydrocarbon gas is provided into the process chamber through the top nozzle at a flow rate of about 5 sccm to about 15 sccm and through the side nozzle at a flow rate of about 160 sccm to about 200 sccm, and the boron-containing gas is provided into the process chamber through the side nozzle at a flow rate of about 10 sccm to about 70 sccm.

### BRIEF DESCRIPTION OF THE DRAWINGS

Features will become apparent to those of ordinary skill in the art by describing in detail exemplary embodiments with reference to the attached drawings, in which:

FIG. 1 illustrates a schematic view of a deposition apparatus that uses induced coupled plasma and that may be utilized for forming a carbon type hard mask layer in accordance with example embodiments;

FIG. 2 illustrates a flow chart relating to a method of forming a carbon type hard mask layer using the deposition apparatus illustrated in FIG. 1;

FIG. 3 illustrates a graph showing carbon densities of amorphous carbon layers formed without applying a bias power and diamond-like carbon layers formed in accordance with example embodiments;

FIG. 4 illustrates a graph showing etching selectivities of hard mask layers formed using a boron-containing gas together with a reactive gas;

FIGS. 5 to 10 illustrate cross-sectional views of stages of a method of forming a pattern in accordance with example embodiments;

FIGS. 11 to 15 illustrate cross-sectional views of stages of a method of forming a pattern in accordance with some example embodiments;

FIGS. 16 to 20 illustrate cross-sectional views of stages of a method of manufacturing a semiconductor device in accordance with example embodiments; and

FIGS. 21 to 29 illustrate cross-sectional views of stages of a method of manufacturing a semiconductor device in accordance with some example embodiments.

It should be noted that these figures are intended to illustrate the general characteristics of methods, structure and/or materials utilized in certain example embodiments and to supplement the written description provided below. It is to be understood that these drawings are not to scale and may not precisely reflect the exact structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope thereof to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

It is to be understood that when an element or layer is referred to as being “on” or “connected to” another element or layer, it can be directly on or connected to the other element or layer, or intervening elements or layers may be present. In contrast, when an element is referred to as being “directly on,” or “directly connected to” another element or layer, there are no intervening elements or layers present. As used herein, the term “and/or” includes any and all combinations of one or more of the associated listed items.

It is to be understood that, although the terms first, second, third, fourth etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “lower,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments may be described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In a method of forming a carbon type hard mask layer using induced coupled plasma (ICP) according to example embodiments, a substrate may be provided in a process chamber of a deposition apparatus using ICP. (Hereinafter the deposition apparatus using ICP is referred to as an “ICP Deposition apparatus.”) A high density plasma (HDP) may be generated in the process chamber, and then a carbon compound gas may be injected into the process chamber. The carbon compound gas may collide with the plasma to be activated so that a diamond-like carbon layer may be deposited on the substrate. The diamond-like carbon layer may be used as a hard mask for forming a pattern of a semiconductor device.

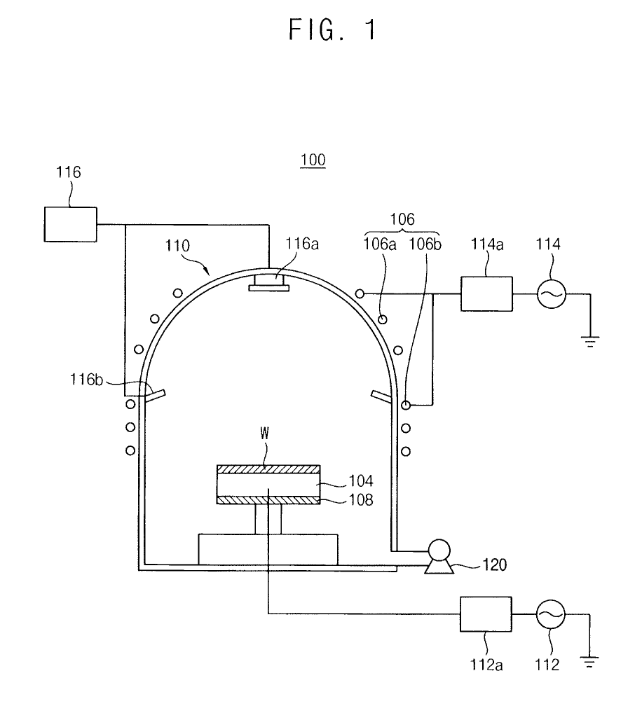

FIG. 1 illustrates a schematic view of an ICP deposition apparatus 100 that may be utilized for forming a carbon type hard mask layer in accordance with example embodiments. The ICP deposition apparatus 100 may include coils disposed outside a chamber. An induced magnetic field may be generated in the coils by changing an electric field applied to the coils. A secondary induced current may be generated in the chamber by the induced magnetic field to produce a plasma in the chamber. A reactive gas for deposition may be provided into the chamber. The reactive gas may be activated by the plasma so that a thin layer may be deposited on an object disposed in the chamber. In example embodiments, the ICP deposition apparatus 100 may be a plasma enhanced chemical vapor deposition (PECVD) apparatus.

Referring to FIG. 1, the ICP deposition apparatus 100 may include a process chamber 110 including a lower electrode 104 and an upper electrode 106, a bias power supply 112 applying a bias power to the lower electrode 104, a source power supply 114 applying a source power to the upper electrode 106, a gas supply 116 providing a reactive gas and a process gas for forming a plasma in the process chamber 110, and a pump 120 for discharging a deposition gas remaining in the process chamber 110.

The gas supply 116 for uniformly injecting the process gas or the reactive gas into the process chamber 110 may be disposed on an upper wall and a sidewall of the process chamber 110. The process chamber 110 may provide a space for generating a plasma from the process gas injected through the gas supply 116. The process chamber 110 may also provide a space for depositing a thin layer on a substrate W using the plasma. In one example embodiment, the process chamber 110 may be substantially cylindrically shaped. In one example embodiment, the process chamber may include an upper portion that is substantially dome shaped.

The lower electrode 104 may be located at a lower portion of the process chamber 110. The lower electrode 104 may be substantially disk shaped. A bias power may be transferred through the lower electrode 104 so that the reactive gas activated by the plasma may be directed to the substrate W. The lower electrode 104 may also serve as a chuck supporting the substrate W in the process chamber 110.

The substrate W may be located on the lower electrode 104. The substrate W may be loaded onto or unloaded from the lower electrode 104 by a plurality of lift pins (not illustrated) that may be disposed through the lower electrode 104 in a vertical direction. The lift pins may be operated to move in a vertical direction by a lifter (not illustrated) combined with a lower portion of the lower electrode 104.

In example embodiments, a cryostat 108 for decreasing a temperature of the substrate W located on the lower electrode 104 may be disposed under the lower electrode 104. The cryostat 108 may direct a low-temperature helium gas toward a bottom of the lower electrode 104. In example embodiments, the temperature of the substrate W may be maintained at about 75° C. to about 300° C. by the cryostat 108.

The upper electrode 106 may be disposed at an upper portion of the process chamber 110 substantially facing the lower electrode 104. The upper electrode 106 may include top coils 106a disposed on the upper wall of the process chamber 110 and side coils 106b disposed on the sidewall of the process chamber 110.

The bias power supply 112 may be connected to the lower electrode 104 to transfer a bias power thereto. The source power supply 114 may be connected to the upper electrode 106 to transfer a source power thereto. The source power supply 114 may transfer a first source power through the top coils 106a and a second source power through the side coils 106b.

The source power supply 114 may apply the source power through the upper electrode 106 to interact with the process gas introduced into the process chamber 110 so that the plasma may be generated from the process gas. The bias power supply 112 may apply the bias power through the lower electrode 104 so that the reactive gas ionized by a collision with the plasma may be accelerated toward the substrate W.

The source power and the bias power may be variably adjusted. A bias controller 112a for adjusting the bias power may be connected to the bias power supply 112, and a source controller 114a for adjusting the source power may be connected to the source power supply 114. Thus, the source power and the bias power may be adjusted within a predetermined range by the source power controller 114a and the bias controller 112a during a formation of a thin layer on the substrate W.

In example embodiments, the source power may be applied at a fixed value, and the bias power may be adjusted according to the desired deposition thickness and density of the thin layer. For example, the first source power may be in a range of about 1300 W to about 1700 W, and the second source power may be in a range of about 3800 W to about 4200 W. To obtain a thin layer with high density, the bias power may be applied in a range of about 900 W to about 1100 W. In another implementation, to rapidly obtain a thin layer having a relatively large thickness, the bias power may be applied in a range of about 500 W to about 900 W, or in a range of about 900 W to about 2000 W.

The gas supply 116 may be connected to a top nozzle located at the upper portion of the process chamber 110 and a side nozzle 116b disposed at the sidewall of the process chamber 110. The gas supply 116 may provide the reactive gas for the deposition of the thin layer and the process gas for generating the plasma into the process chamber 110 through the top nozzle 116a and the side nozzle 116b.

According to example embodiments, the high-density plasma may be generated by the ICP deposition apparatus 100 so that a carbon type layer may be formed at a high deposition rate. Further, the bias power may be adjusted to generate adequate ion bombardment energy so that a crystallinity of the thin layer may be controlled. Thus, the thin layer having a high density and high transparency may be formed on the substrate W even at a low temperature. If a hydrocarbon compound gas is used as the reactive gas, a diamond-like carbon layer, useful as a hard mask layer, may be obtained.

Hereinafter, methods of forming a carbon type hard mask layer on a substrate utilizing the ICP deposition apparatus illustrated in FIG. 1 are described.

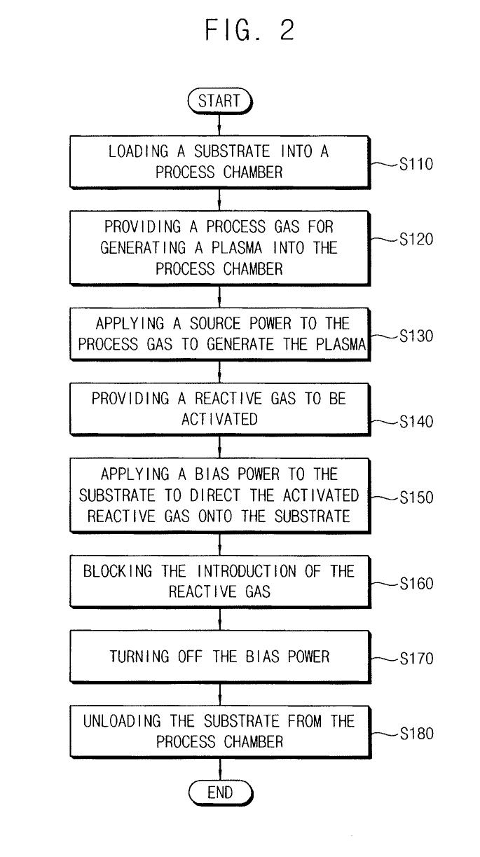

FIG. 2 illustrates a flow chart relating to a method of forming a carbon type hard mask layer using the apparatus illustrated in FIG. 1

In S110, a substrate W on which a deposition process is to be performed may be loaded into a process chamber 110. The substrate W may be loaded onto a lower electrode 104 disposed at a lower portion of the process chamber 110. An internal pressure of the process chamber 110 may be maintained within a range of about 5 mTorr to about 8 mTorr.

In example embodiments, the substrate W may be maintained at a relatively low temperature by a cryostat 108 that directs a low-temperature helium gas onto a bottom of the lower electrode 104. For example, the temperature of the substrate W may be maintained within a range of about 75° C. to about 300° C. Therefore, the transparency of the resultant carbon type hard mask layer may be enhanced.

In S120, a process gas for generating a plasma in the process chamber 110 may be provided. The process gas may include an inert gas, for example, helium (He) gas, argon (Ar) gas, etc. For example, a helium gas may be dispersed through a top nozzle 116a and/or a side nozzle 116b at a flow rate of about 210 sccm to about 300 sccm. An argon gas may be provided through the side nozzle 116b at a flow rate of about 150 sccm to about 210 sccm.

In S130, a source power may be applied to generate the plasma from the process gas. A source power supply 114 connected to an upper electrode 106 may apply the source power to the process gas in the process chamber 110 so that ions in a plasma state are generated from the process gas. The ions in the plasma state may include positively charged particles, negatively charged particles and electrons. The source power may include a first source power applied to top coils 106a and a second source power applied to side coils 106b. The first source power may be in a range of about 1300 W to about 1700 W, and the second source power may be in a range of about 3800 W to about 4200 W.

In S140, a reactive gas that is activated by the plasma to be deposited in the formation of a diamond-like carbon layer may be provided into the process chamber 110. In example embodiments, the reactive gas may include a hydrocarbon compound gas such as C₃H₆, C₄H₈, C₆H₁₂, etc. The ions in the plasma state and the hydrocarbon compound gas may collide with each other intensively to produce ionized carbon particles. The hydrocarbon compound gas may be introduced through both the top nozzle 116a and the side nozzle 116b so as to be provided uniformly onto a whole surface of the substrate W. For example, the hydrocarbon compound gas may be introduced through the top nozzle 116a at a flow rate of about 5 sccm to about 15 sccm and through the side nozzle 116b at a flow rate of about 160 sccm to about 200 sccm. When the flow rate of the hydrocarbon compound gas is greater than or less than the above range, the hydrocarbon compound gas may not be dispersed uniformly on the substrate W, resulting in the diamond-like carbon layer having irregular thickness.

In example embodiments, the reactive gas may further include a boron-containing gas. For example, the boron-containing gas may include borane (BH₃), diborane (B₂H₆), boron trifluoride (BF₃), etc. These may be used alone or in a mixture thereof. In one example embodiment, the reactive gas may further include hydrogen (H₂) gas together with the boron-containing gas.

In example embodiments, the boron-containing gas may be introduced through the side nozzle 116b at a flow rate of about 10 sccm to about 70 sccm. When the flow rate of the boron-containing gas is less than about 10 sccm, a carbon density of the resultant diamond-like carbon layer may not be sufficiently enhanced, or a residual stress of the diamond-like carbon layer may not be sufficiently removed. When the flow rate of the boron-containing gas is greater than 70 sccm, an sp³ hybridized structure of the diamond-like carbon layer may be deformed or modified.

In S150, a bias power may be applied to the substrate W to direct the activated reactive gas onto the substrate W. The bias power may be applied after a cessation of applying the source power. The bias power may be applied to the substrate W through a bias power supply 112 connected to the lower electrode 104. The bias power may be in a range of about 500 W to about 2000 W so that the activated and ionized carbon particles may form the diamond-like carbon layer on the substrate W. The ionized carbon particles may be guided or directed toward the substrate W by the bias power.

The diamond-like carbon layer in which a 3-dimensional structure, e.g., a tetrahedral structure of diamond is dominant over a 2-dimensional structure of graphite may be obtained by adjusting the bias power. The diamond-like carbon layer may have an sp³ hybridized structure. The sp^{a} hybridized structure may have a hardness and transparency greater than the hardness and transparency of a sp² hybridized structure. Thus, the diamond-like carbon layer formed on the substrate W may have a high transparency and carbon density and may have an excellent etching selectivity when used as a hard mask layer.

In example embodiments, the bias power may be adjusted according to a desired density and thickness of the diamond-like carbon layer. For example, the bias power may be in a range of about 900 W to about 1100 W to form a diamond-like carbon layer with a high density. In other implementations, the bias power may be in a range of about 500 W to about 900 W or about 1100 W to about 2000 W to form a diamond-like carbon layer having a greater thickness.

When a hard mask layer is formed of amorphous carbon at a relatively low temperature (e.g., less than about 350° C.), the transparency of the hard mask layer may be enhanced to provide a low absorption coefficient (k) of, e.g., about 0.01. However, the carbon density of the hard mask layer may be decreased, thereby providing a poor etching selectivity. On the other hand, when the hard mask layer is formed at a relatively high temperature (e.g., greater than about 550° C.), the carbon density of the hard mask layer may be enhanced. However, the transparency of the hard mask layer may be reduced. For example, the hard mask layer may have a high absorption coefficient of, e.g., about 0.4. Accordingly, a misalignment of the hard mask layer may be caused, which may result in a formation of defective patterns during an etching process.

According to example embodiments, the substrate W may be maintained at a relatively low temperature while the diamond-like carbon layer is formed using the ICP deposition apparatus 100. Thus, the transparency of the diamond-like carbon layer may be enhanced. For example, the absorption coefficient of the diamond-like carbon layer may be in a range of about 0.05 to about 0.09.

Additionally, the crystallinity and carbon density of the diamond-like carbon layer may be enhanced by selectively adjusting the source power and the bias power, so that the carbon type hard mask layer having a high etching selectivity may be obtained.

As described above, a boron-containing gas may be further included in the reactive gas so that the crystallinity of the diamond-like carbon layer may be enhanced. Further, a residual stress in the diamond-like carbon layer may be efficiently removed by the addition of the boron-containing gas. Such residual stress may interrupt a formation of a hard mask layer having a sufficient thickness, so that a pattern having a high aspect ratio may not be easily formed. In example embodiments, the residual stress may be reduced while maintaining the sp³ hybridized structure of the diamond-like carbon layer by adding the boron-containing gas to the reactive gas.

In S160, when the deposition process of the diamond-like carbon layer is completed, the introduction of the reactive gas may be blocked.

In S170, the bias power may be turned off. In S180, the remaining process gas and residual particles in the process chamber 110 may be pumped out of the process chamber 110 to form a vacuum state. Thereafter, the substrate W may be unloaded from the process chamber 110.

According to example embodiments, a hydrocarbon compound gas may be activated by the high density plasma using the ICP deposition apparatus, so that a diamond-like carbon layer may be rapidly deposited. Further, adequate ion bombardment energy may be applied to the substrate W by adjusting the bias power, so that the crystallinity of the diamond-like carbon layer may be enhanced. Therefore, a hard mask layer having desired transparency and etching selectivity may be obtained.

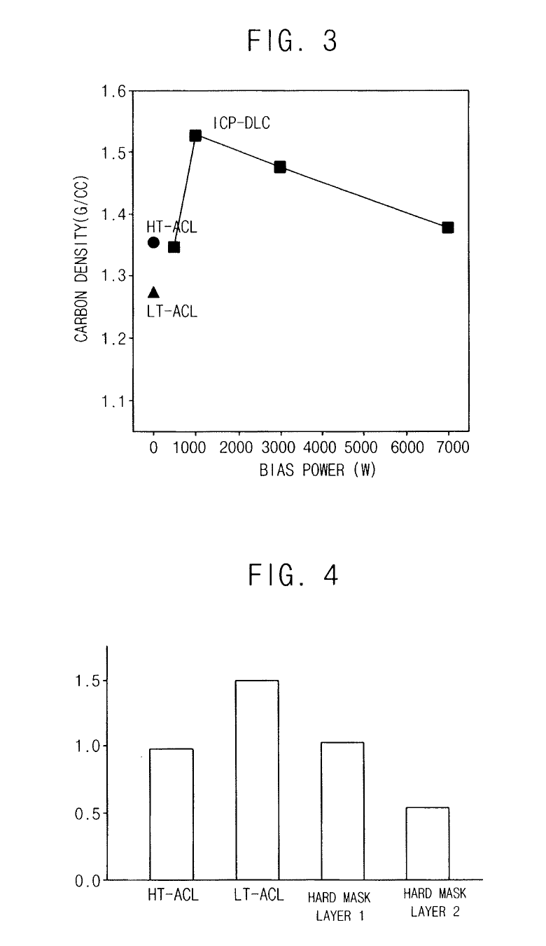

FIG. 3 illustrates a graph showing carbon densities of amorphous carbon layers formed without applying a bias power and diamond-like carbon layers formed in accordance with example embodiments.

In FIG. 3, symbols “▴” and “” indicate carbon densities of a low temperature amorphous carbon layer (LT-ACL) formed at about 350° C. and a high temperature carbon layer (HT-ACL) formed at about 550° C., respectively. Both the LT-ACL and the HT-ACL were formed without applying a bias power. A symbol “▪” indicates the carbon density of diamond-like carbon layers formed at about 75° C. using the ICP deposition apparatus according to example embodiments (hereinafter, these layers are referred to as ICP-DLCs). A bias power was applied at 500 W, 1000 W, 3000 W and 7000 W.

Referring to FIG. 3, the carbon density of the ICP-DLCs increased until the bias power reached about 1000 W. The carbon density decreased when the bias power was greater than about 1000 W. A maximum value of the carbon density of the ICP-DLCs was found to be about 1.55 g/cc at the bias power of about 1000 W.

The carbon densities of the HT-ALC and the LT-ACL were found to be about 1.36 g/cc and about 1.28 g/cc, respectively. Thus, the LT-ACL, which has a good transparency (k=0.1) may have a low carbon content or low carbon density, resulting in a poor etching selectivity. Accordingly, the LT-ACL may not be desirable for a hard mask used for a formation of a pattern having a high aspect ratio. On the other hand, the HT-ACL may have a poor transparency (k=0.4).

As shown in FIG. 3, an ICP-DLC having a good transparency while having a carbon density higher than that of the HT-ACL may be obtained by adjusting the bias power.

FIG. 4 illustrates a graph showing etching selectivities of hard mask layers formed using a boron-containing gas together with a reactive gas

Referring to FIG. 4, “HT-ACL” and “LT-ACL” represent amorphous carbon layers formed at about 550° C. and about 350° C., respectively, without applying a bias power. “Hard mask 1” and “hard mask 2” represent ICP-DLCs formed in an ICP process using a boron-containing gas at a flow rate of about 25 sccm and of about 50 seem, respectively, together with a hydrocarbon compound gas as a reactive gas. The applied bias power was about 1000 W.

Etching rates for the HT-ACL, the LT-ACL, the hard mask 1 and the hard mask 2 were measured while performing a plasma etching process with respect to each layer under the same process condition. In FIG. 4, each etching rate is indicated by a ratio with respect to the etching rate for the HT-ACL which is set as 1.0.

Referring to FIG. 4, the hard mask 1 and the hard mask 2 are shown to have etching rates less than that of the LT-ACL. Particularly, the hard mask 2 is shown to have an etching rate that corresponds to about 40% of the etching rate of the HT-ACL (i.e., about 0.6). Thus, the hard mask 2 may have an etching selectivity that is improved by about 40% compared to the etching selectivity of the HT-ACL.

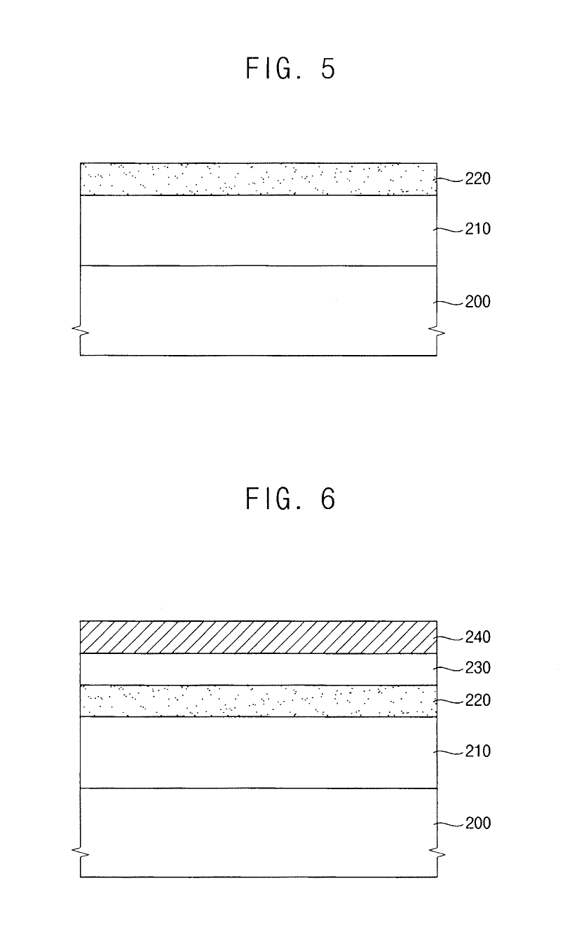

FIGS. 5 to 10 illustrate cross-sectional views relating to stages of a method of forming a pattern in accordance with example embodiments. Specifically, FIGS. 5 to 10 illustrate stages of a method of forming a trench or a contact hole in accordance with example embodiments.

Referring to FIG. 5, an insulation layer 210 may be formed on a substrate 200, and a hard mask layer 220 having a high transparency and an etching selectivity greater than that of an amorphous carbon layer may be formed on the insulation layer 210.

A lower structure (not illustrated) including, for example, a switching device such as a transistor, an impurity region, a conductive pattern, etc., may be foamed on the substrate 200.

The insulation layer 210 covering the lower structure may be formed on the substrate 200. The insulation layer 210 may be formed of an insulation material including, e.g., silicon oxide, silicon nitride or silicon oxynitride, by a chemical vapor deposition (CVD) process, a plasma enhanced chemical vapor deposition (PECVD) process, a low pressure chemical vapor deposition (LPCVD) process, a spin coating process, etc. An upper portion of the insulation layer 210 may be planarized by, e.g., a chemical mechanical polishing (CMP) process or an etch-back process.

The hard mask layer 220 may be formed by processes substantially the same as or similar to those described with reference to FIG. 2. For example, the hard mask layer 220 may be formed as a diamond-like carbon layer by a deposition process using the ICP deposition apparatus illustrated in FIG. 1, for example, by an ICP-PECVD process. A process gas for generating a plasma may include helium gas or argon gas. A reactive gas that may be activated by a collision with the plasma to form the hard mask layer 220 on the insulation layer 210 may include a hydrocarbon compound gas including, e.g., C₃H₆, C₄H₈ or C₆H₁₂. In some example embodiments, the reactive gas may further include a boron-containing gas such as borane (BH₃), diborane (B₂H₆), boron trifluoride (BF₃), etc. The reactive gas may further include hydrogen gas together with the boron-containing gas.

In example embodiments, a bias power in a range of about 500 W to about 2000 W may be applied to the substrate 200. The reactive gas may be introduced from a top nozzle 116a and a side nozzle 116b of the ICP deposition apparatus 100 (see FIG. 1) to be uniformly provided on a whole surface of the insulation layer 210. In one example embodiment, the hard mask layer 220 may be formed to have a thickness of from about 1500 Å to about 2500 Å.

The hard mask layer 220 may have a low absorption coefficient of from about 0.05 to about 0.09 to provide a high transparency. Further, the hard mask layer 220 may have a carbon density of from about 1.4 g/cc to about 1.7 g/cc so that the hard mask layer 220 may have an etching selectivity greater than that of an amorphous carbon layer.

Referring to FIG. 6, an anti-reflective layer 230 and a photoresist layer 240 may be sequentially formed on the hard mask layer 220.

The anti-reflective layer 230 may prevent light reflection from the hard mask layer 220 during a subsequent exposure process and may reduce a standing wave effect generated at a sidewall of a hard mask layer pattern during a developing process after the exposure process. In one example embodiment, the anti-reflective layer 230 may have a thickness of from about 300 Å to about 450 Å to effectively prevent the light reflection.

The photoresist layer 240 may be formed by spin coating a positive type photoresist composition or a negative type photoresist composition on the anti-reflective layer 230. For example, the positive type photoresist composition may include acetal based, T-BOC based or acrylate based materials. The photoresist layer 240 may have a thickness from about 1500 Å to about 2500 Å.

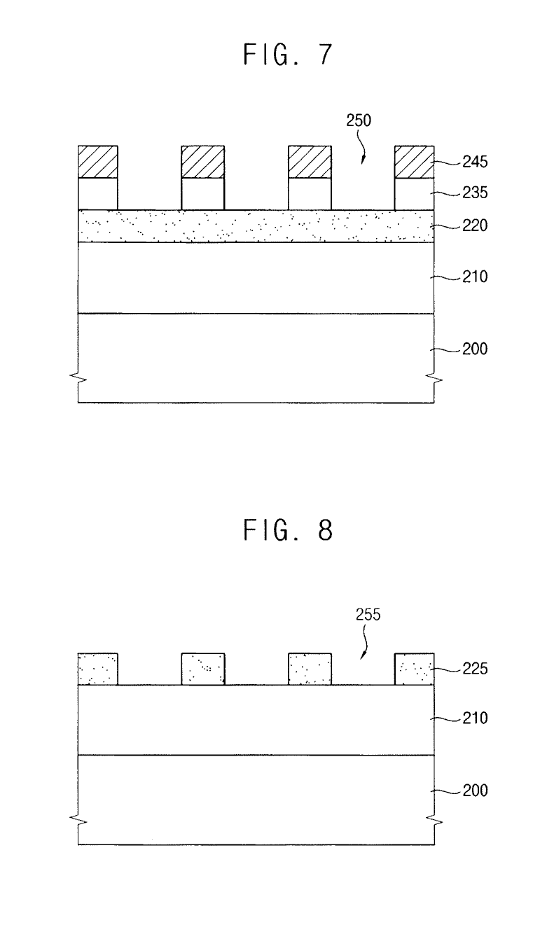

Referring to FIG. 7, exposure and developing processes may be performed on the photoresist layer 240 to form a photoresist layer pattern 245. The anti-reflective layer 230 may be partially removed using the photoresist pattern 245 as an etching mask to form an anti-reflective layer pattern 235. Accordingly, a first opening 250 partially exposing the hard mask layer 220 may be formed.

Referring to FIG. 8, the hard mask layer 220 may be partially removed using the photoresist pattern 245 and the anti-reflective layer pattern 235 as an etching mask to form a hard mask layer pattern 225. The photoresist pattern 245 and the anti-reflective layer pattern 235 may be substantially removed during the etching process. A second opening 255 partially exposing the insulation layer 210 may be defined by forming the hard mask layer pattern 225.

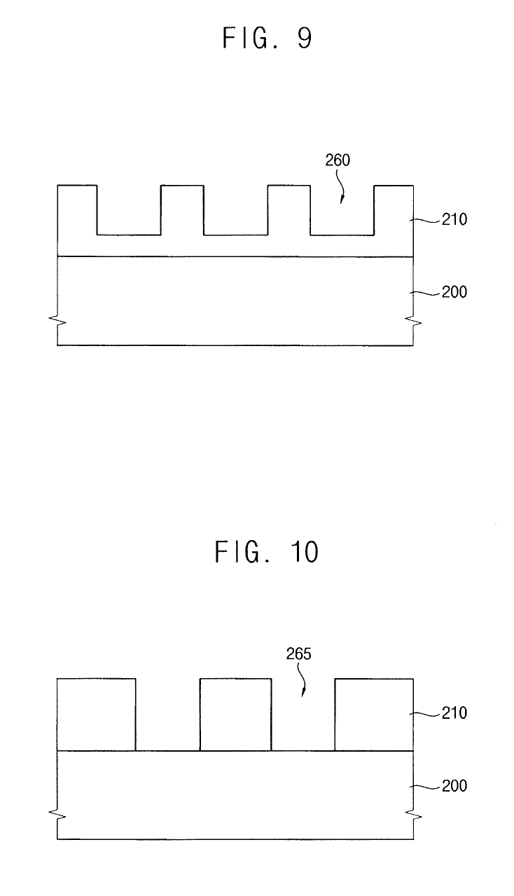

Referring to FIG. 9, the insulation layer 210 may be partially removed using the hard mask layer pattern 225 as an etching mask to form a trench 260 in the insulation layer 210. In example embodiments, a wiring structure (not illustrated) or a conductive pattern (not illustrated) having a high aspect ratio may be formed in the trench 260. The hard mask layer pattern 225 may have a carbon density greater than that of a hard mask formed of amorphous carbon while maintaining a high transparency. Accordingly, the hard mask layer pattern 225 may have an excellent etching selectivity with respect to the insulation layer 210. Thus, the trench 260 having a fine line width and a large depth may be formed in the insulation layer 210 using the hard mask layer pattern 225.

In some example embodiments, the insulation layer 210 may be partially removed using the hard mask layer pattern 225 as an etching mask to form a contact hole that may expose a predetermined region of the substrate 200. In example embodiments, a conductive region (not illustrated), e.g., an impurity region formed on the substrate 200 may be exposed by the contact hole 265. A conductive structure (not illustrated) including, e.g., a contact or a plug may be formed in the contact hole 265 to be electrically connected to the conductive region. The conductive structure may serve as, for example, a capacitor contact of a dynamic random access memory (DRAM) device, a channel of a vertical semiconductor memory device, a bit line contact of DRAM or flash memory devices, etc.

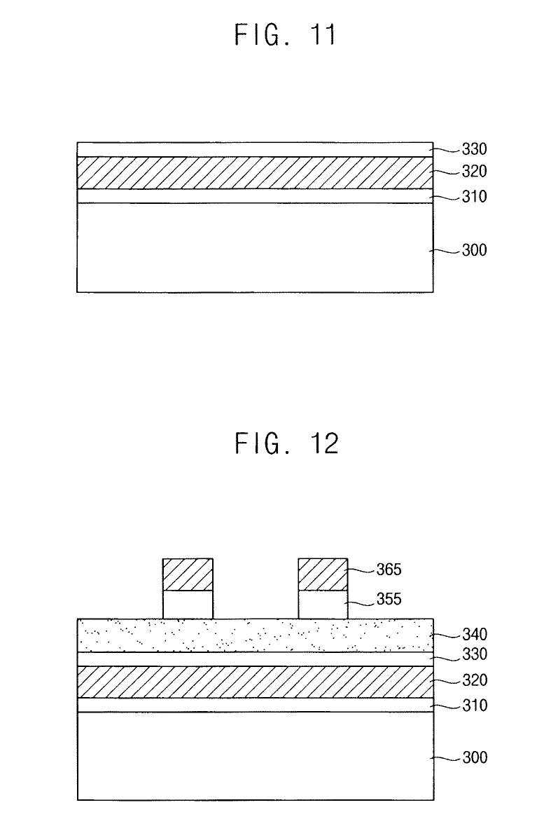

FIGS. 11 to 15 illustrate cross-sectional views relating to stages of a method of forming a pattern in accordance with some example embodiments. Specifically, FIGS. 11 to 15 illustrate stages of a method of forming a gate structure in accordance with some example embodiments.

Referring to FIG. 11, a gate insulation layer 310, a gate conductive layer 320 and a gate mask layer 330 may be sequentially formed on a substrate 300.

The substrate 300 may include a semiconductor substrate, e.g., a single crystalline silicon substrate. The gate insulation layer 310 may be formed using an insulating material, e.g., silicon oxide, by a CVD process. In other implementations, the gate insulation layer 310 may be formed by performing a thermal oxidation process on the substrate. The gate conductive layer 320 may be formed using doped polysilicon or a metal such as titanium or tungsten. The gate conductive layer 320 may be obtained by, e.g., a CVD process, a physical vapor deposition (PVD) process, a sputtering process, an atomic layer deposition (ALD) process, etc. The gate mask layer 330 may be formed using silicon nitride by, e.g., a CVD process.

Referring to FIG. 12, a hard mask layer 340 may be formed on the gate mask layer 330. An anti-reflective layer pattern 355 and a photoresist layer pattern 365 may be sequentially formed on the hard mask layer 340.

The hard mask layer 340 may be formed by processes substantially the same as or similar to those illustrated with reference to FIG. 2 or FIG. 5.

The anti-reflective layer pattern 355 and the photoresist layer pattern 365 may be formed by processes substantially the same as or similar to those illustrated with reference to FIGS. 5 to 7.

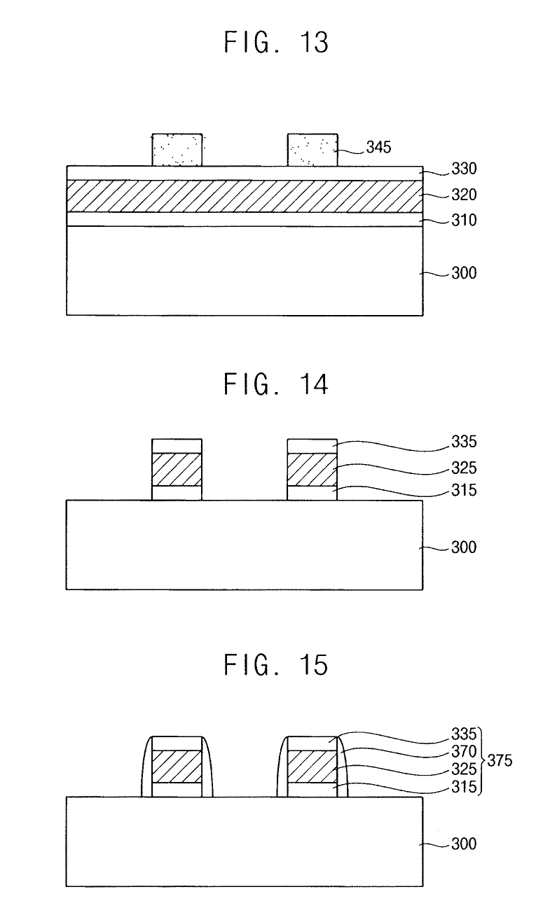

Referring to FIG. 13, the hard mask layer 340 may be partially removed using the photoresist layer pattern 365 and the anti-reflective layer pattern 355 as an etching mask to form a hard mask layer pattern 345. The photoresist layer pattern 365 and the anti-reflective layer pattern 355 may be substantially removed during the etching process.

Referring to FIG. 14, the gate mask layer 330 may be partially removed using the hard mask layer pattern 345 as an etching mask to form a gate mask 335. The gate conductive layer 320 and the gate insulation layer 310 may be sequentially etched using the hard mask layer pattern 345 and the gate mask 335 as an etching mask to form a gate electrode 325 and a gate insulation layer pattern 315. In example embodiments, the hard mask layer pattern 345 may have a high etching selectivity so that the hard mask layer pattern 345 is not removed or damaged during the etching process. After the etching process, the hard mask layer pattern 345 may be removed by, e.g., an ashing process or a strip process.

Referring to FIG. 15, a spacer 370 may be formed on a sidewall of the gate insulation layer pattern 315, the gate electrode 325 and the gate mask 335. For example, a spacer layer (not illustrated) covering the gate insulation layer pattern 315, the gate electrode 325 and the gate mask 335 may be formed on the substrate 300. The spacer layer may be anisotropically etched to form the spacer 370. Accordingly, a gate structure 375 including the gate insulation layer pattern 315, the gate electrode 325, the gate mask 335 and the spacer 370 may be obtained.

In example embodiments, the hard mask layer 340 or the hard mask layer pattern 345 may include a diamond-like carbon layer with high etching selectivity and transparency. Therefore, the gate structure 375 may be formed using the hard mask layer pattern 345 as the etching mask without generating defects or a misalignment

The method of forming the gate structure illustrated in FIGS. 11 to 15 may be employed for forming a gate structure of a flash memory device. For example, the method may be used for forming a gate structure of a floating gate type memory device that includes a tunnel insulation layer pattern, a floating gate, a dielectric layer pattern and a control gate. The method may be also employed for forming a gate structure of a charge-trapping type memory device that includes a tunnel insulation layer pattern, a charge-trapping layer pattern, a blocking layer pattern and a gate electrode.

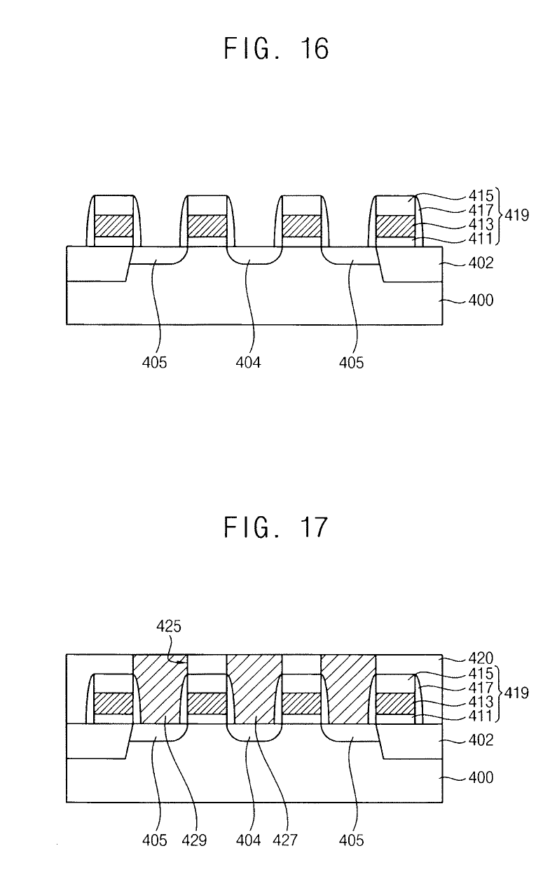

FIGS. 16 to 20 illustrate cross-sectional views relating to stages of a method of manufacturing a semiconductor device in accordance with example embodiments. Specifically, FIGS. 16 to 20 illustrate stages of a method of manufacturing a DRAM device.

Referring to FIG. 16, an isolation layer 402 may be formed on a substrate 400. The isolation layer 402 may be formed by a shallow trench isolation (STI) process.

A gate structure 419 including a gate insulation layer pattern 411, a gate electrode 413, a gate mask 415 and a spacer 417 may be formed on the substrate 400. In example embodiments, the gate structure 419 may be formed by processes substantially the same as or similar to those illustrated with reference to FIGS. 11 to 15.

Impurities may be implanted into the substrate 400 using the gate structures 419 as an ion-implantation mask to form first and second impurity regions 404 and 405 at upper portions of the substrate 400 adjacent to the gate structures 419. Transistors may be defined by the gate structure 419 and the impurity regions 404 and 405. The first and second impurity regions 404 and 405 may serve as source/drain regions of the transistors.

Referring to FIG. 17, a first insulating interlayer 420 covering the gate structures 419 may be formed on the substrate 400. The first insulating interlayer 420 may be partially etched to form first contact holes 425 exposing the first and second impurity regions 404 and 405. In example embodiments, the first contact holes 425 may be formed by processes substantially the same as or similar to those illustrated with reference to FIGS. 5 to 10.

A first conductive layer sufficiently filling the first contact holes 425 may be formed on the first insulating interlayer 420. An upper portion of the first conductive layer may be planarized by a CMP process and/or an etch-back process to form first and second plugs 427 and 429. The first and second plugs 427 and 429 may make contact with the first and second impurity regions 404 and 405, respectively. The first conductive layer may be formed using doped polysilicon, a metal, etc.

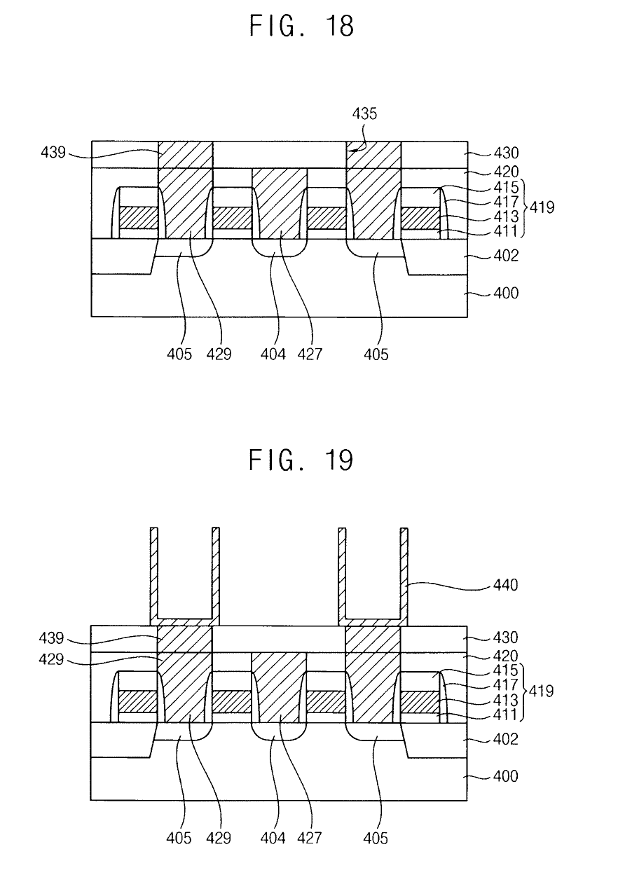

Referring to FIG. 18, a second conductive layer (not illustrated) contacting the first plug 427 may be formed on the first insulating interlayer 420. The second conductive layer may be patterned to form a bit line (not illustrated). The second conductive layer may be formed using doped polysilicon, a metal, etc. In this case, the first plug 427 may serve as a bit line contact.

A second insulating interlayer 430 covering the bit line may be formed on the first insulating interlayer 420. The second insulating interlayer 430 may be partially removed to form second contact holes 435 exposing the second plugs 429. The second contact holes 435 may be formed by processes substantially the same as or similar to those illustrated with reference to FIGS. 5 to 10.

A third conductive layer sufficiently filling the second contact holes 435 may be formed on the second plugs 429 and the second insulating interlayer 430. An upper portion of the third conductive layer may be planarized by a CMP process and/or an etch-back process to form third plugs 439. The third conductive layer may be formed using doped polysilicon, a metal, etc. The second and third plugs 429 and 439 may serve as capacitor contacts. In other implementations, the third plug 439 may directly make contact with the second impurity region 405 through the first and second insulating interlayers 420 and 430 without forming the second plug 429.

Referring to FIG. 19, an etch-stop layer (not illustrated) and a mold layer (not illustrated) may be formed on the second insulating interlayer 430. The mold layer and the etch-stop layer may be partially removed to form an opening (not illustrated) exposing a top surface of the third plug 439. The mold layer may be formed using silicon oxide, and the etch-stop layer may be formed using silicon nitride.

In example embodiments, the opening may be formed by processes substantially the same as or similar to those illustrated with reference to FIGS. 5 to 10.

A lower electrode layer may be formed on a sidewall and a bottom of the opening and on a top surface of the mold layer. The lower electrode layer may be formed using a metal or a metal nitride, e.g., titanium, titanium nitride, tantalum, tantalum nitride, tungsten nitride, ruthenium, etc., or doped polysilicon. A sacrificial layer may be formed on the lower electrode layer using silicon oxide, and then the sacrificial layer and the lower electrode layer may be partially removed to expose the top surface of the mold layer. The sacrificial layer and the mold layer may be removed to form a lower electrode 440 electrically connected to the third plug 439. For example, the sacrificial layer and the mold layer may be removed by a wet etching process using an etching solution that has an etching selectivity for silicon oxide.

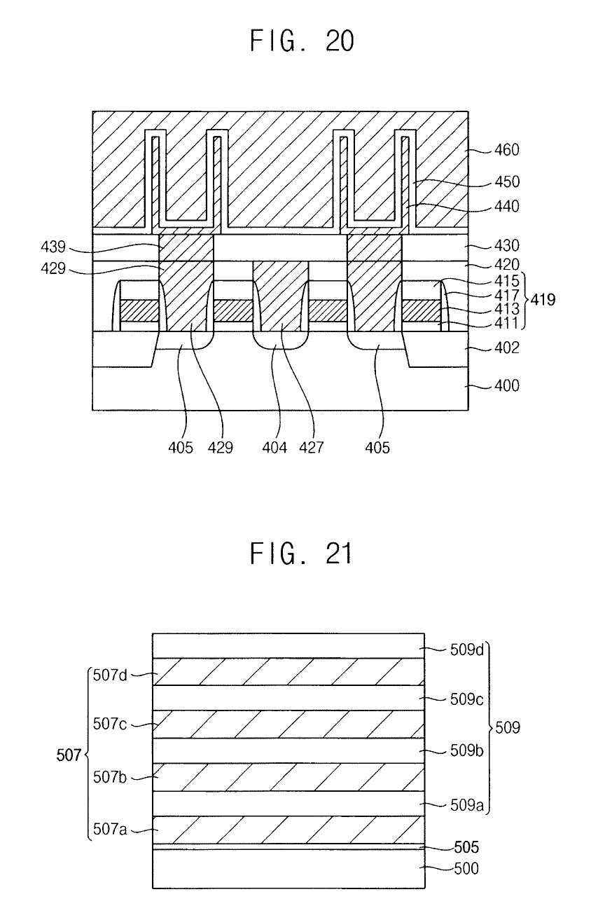

Referring to FIG. 20, a dielectric layer 450 covering the lower electrode 440 may be formed on the etch-stop layer and the second insulating interlayer 430. The dielectric layer may be formed using a material that has a dielectric constant higher than that of silicon oxide or silicon nitride.

An upper electrode 460 may be formed on the dielectric layer 450. The upper electrode 460 may be formed using a metal and/or a metal nitride such as titanium, titanium nitride, tantalum, tantalum nitride, tungsten nitride, ruthenium, etc.

Accordingly, a capacitor including the lower electrode 440, the dielectric layer 450 and the upper electrode 460 may be obtained.

As described above, the DRAM device including a plug, a contact or a capacitor that have high aspect ratios may be obtained utilizing the method of forming a pattern, e.g., a contact hole or an opening according to example embodiments.

FIGS. 21 to 29 illustrate cross-sectional views relating to stages of a method of manufacturing a semiconductor device in accordance with some example embodiments. Specifically, FIGS. 21 to 29 illustrate states of a method of manufacturing a vertical memory device.

Referring to FIG. 21, a pad insulation layer 505 may be formed on a substrate 500. Sacrificial layers 507 and insulating interlayers 509 may be repeatedly and alternately formed on the pad insulation layer 505 in a direction vertical to a top surface of the substrate 500. That is, a first sacrificial layer 507a may be formed on the pad insulation layer 505, and a first insulating interlayer 509a may be formed on the first sacrificial layer 507a. Likewise, other sacrificial layers 507b, 507c and 507d and insulating interlayers 509b, 509c and 509d may be sequentially and alternately formed on each other.

The pad insulation layer 505 may reduce stress that may be generated if the first sacrificial layer 507a were to be formed directly on the substrate 500. The pad insulation layer 505 may be formed by performing a thermal oxidation process on the substrate 500.

The sacrificial layers 507 may be removed by a subsequent process to define regions in which gate structures are formed according to levels of the vertical memory device. The sacrificial layers 507 may be formed using a material that has an etching selectivity with respect to the insulating interlayers 509. In example embodiments, the sacrificial layers 507 and the insulating interlayers 509 may be formed using silicon nitride and silicon oxide, respectively. The sacrificial layers 507 and the insulating interlayers 509 may be obtained by a CVD process, a PECVD process, a spin coating process, an HDP-CVD process, etc.

A transistor at each level may be formed in a space generated when the sacrificial layer 507 is removed. Thus, the number of the sacrificial layers 507 may be greater than or equal to the number of the transistors of a string, including cell transistors and selection transistors.

In example embodiments, the string may include four (4) cell transistors and two (2) selection transistors. In other implementations, the number of cell transistors and selection transistors may be adjusted as desired.

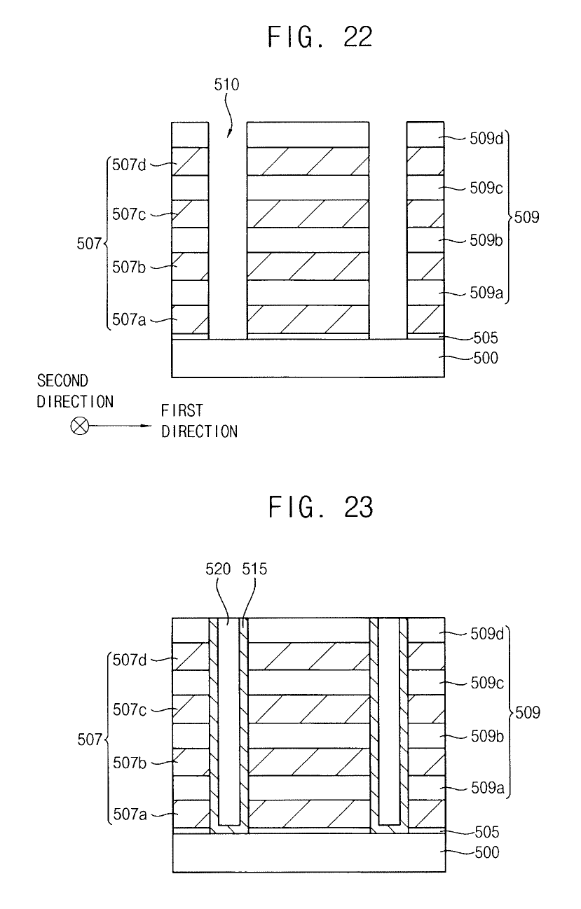

Referring to FIG. 22, the insulating interlayers 509, the sacrificial layers 507 and the pad insulation layer 505 may be sequentially etched to form a first hole 510. The top surface of the substrate 500 may be exposed by a bottom of the first hole 510. In example embodiments, a plurality of the first holes 510 may be formed regularly in a first direction and in a second direction substantially perpendicular to the first direction.

In example embodiments, the first hole 510 may be formed by processes substantially the same as or similar to those illustrated with reference to FIGS. 5 to 10.

Referring to FIG. 23, a semiconductor pattern 515 may be formed on an inner wall of the first hole 510 and the substrate 500. The semiconductor pattern 515 may serve as a channel or an active region of a cell string formed vertically relative to the top surface of the substrate 500. In example embodiments, the semiconductor pattern 515 may have a hollow cylindrical shape or a cup shape. The semiconductor pattern 515 may be formed using polysilicon or amorphous silicon.

An insulation layer sufficiently filling the first hole 510 may be formed on the semiconductor pattern 515 and the uppeil ost insulating interlayer 509d. An upper portion of the insulation layer may be planarized to form a first insulation layer pattern 520.

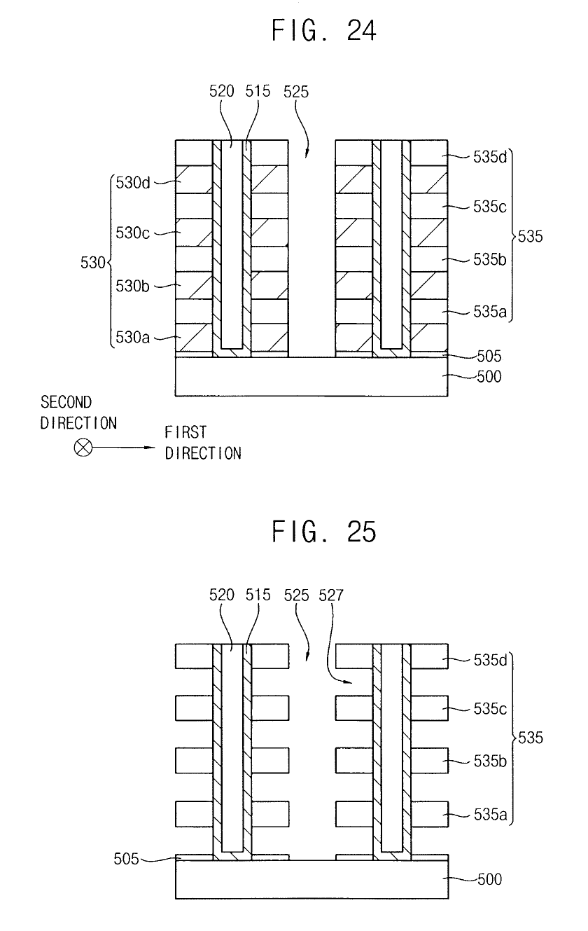

Referring to FIG. 24, the sacrificial layers 507 and the insulating interlayers 509 between the semiconductor patterns 515 may be partially etched to form an opening 525. The opening 525 may extend in the second direction. Sacrificial layer patterns 530 and insulating interlayer patterns 535 extending in the second direction may be formed by forming the opening 525. The sacrificial layer patterns 530 and the insulating interlayer patterns 535 may surround outer sidewalls of the semiconductor patterns 515. In example embodiments, the opening 525 may be formed by processes substantially the same as or similar to those illustrated with reference to FIGS. 5 to 10.

Referring to FIG. 25, the sacrificial layer patterns exposed by a sidewall of the opening 525 may be removed by, e.g., a wet etching process. If the sacrificial layer patterns 530 include silicon nitride, the sacrificial layer patterns 530 may be removed using an etching solution that includes, for example, sulfuric acid or phosphoric acid.

The insulating interlayer patterns 530 may remain on the outer sidewall of the semiconductor pattern 515 to be spaced apart from one another in the vertical direction relative to the top surface of the substrate 500. A plurality of grooves 527 may be defined by spaces generated when the sacrificial layer patterns 530 are removed to partially expose the outer sidewall of the semiconductor pattern 515.

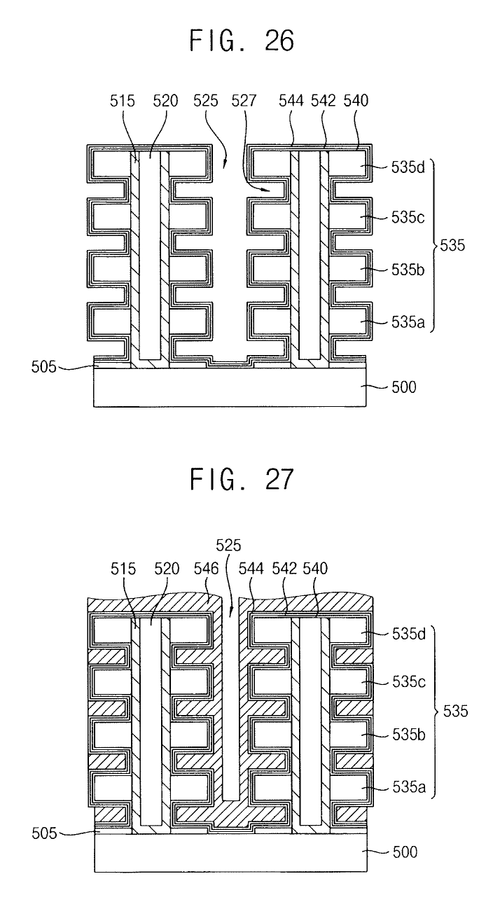

Referring to FIG. 26, a tunnel insulation layer 540, a charge-trapping layer 542 and a blocking layer 544 may be formed sequentially along the exposed outer sidewall of the semiconductor pattern 515 and surfaces of the insulating interlayer patterns 535.

The tunnel insulation layer 540 may be formed using silicon oxide by, e.g., a CVD process. Alternatively, the tunnel insulation layer 540 may be formed only on the exposed outer sidewall of the semiconductor pattern 515 by performing a thermal oxidation process thereon.

The charge-trapping layer 542 may be formed using silicon nitride or a metal oxide by a CVD process, etc.

The blocking layer 544 may be formed on the charge-trapping layer 542. The blocking layer 544 may be formed using silicon oxide or a metal oxide such as aluminum oxide, lanthanum oxide, lanthanum aluminum oxide, lanthanum hafnium oxide, hafnium aluminum oxide, titanium oxide, tantalum oxide, zirconium oxide, etc. These may be used alone or in a mixture thereof.

In example embodiments, the charge-trapping layer 542 and the blocking layer 544 may be continuously formed throughout all levels.

Referring to FIG. 27, a conductive layer 546 may be formed on the blocking layer 544 to sufficiently fill the grooves 527. The opening 525 may be partially filled with the conductive layer 546. The conductive layer 546 may be formed using a metal or a metal nitride having a low resistance, for example, tungsten, tungsten nitride, titanium, titanium nitride, tantalum, tantalum nitride or platinum. The conductive layer 546 may be obtained by a CVD process, an ALD process, a PVD process, etc.

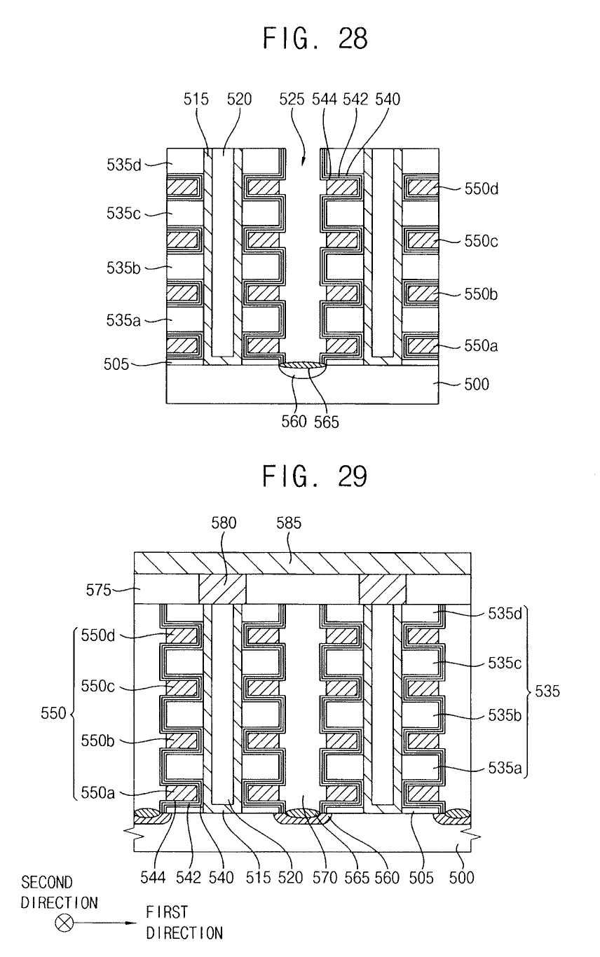

Referring to FIG. 28, the conductive layer 546 may be partially removed to form gate electrodes 550a, 550b, 550c and 550d in the grooves 527.

An upper portion of the conductive layer 546 may be planarized until an uppermost insulating interlayer pattern 535d is exposed. Portions of the tunnel insulation layer 540, the charge-trapping layer 542 and the blocking layer 544 formed on a top surface of the uppermost insulating interlayer pattern 535d may be also removed. A portion of the conductive layer 546 in the opening 525 may be removed by, e.g., a dry etching process to form the gate electrodes 550a, 550b, 550c and 550d. Portions of the tunnel insulation layer 540, the charge-trapping layer 542 and the blocking layer 544 on the bottom of the opening 525 may be also removed to expose the top surface of the substrate 500.

In some example embodiments, portions of the tunnel insulation layer 540, the charge-trapping layer 542 and the blocking layer 544 formed on sidewalls of the insulating interlayer patterns 535 may be also removed together with the portion of the conductive layer 546 in the opening 525. In this case, the tunnel insulation layer 540, the charge-trapping layer 542 and the blocking layer 544 at different levels may be separated from each other.

By performing the above processes, a gate structure including the tunnel insulation layer 540, the charge-trapping layer 542, the blocking layer 544 and the gate electrode 550 may be formed in each groove 527. In example embodiments, the lowermost gate electrode 550a may serve as a ground selection line (GSL) and the uppermost gate electrode 550d may serve as a string selection line (SSL). The gate electrodes 550b and 550c between the GSL and the SSL may serve as word lines.

Referring now to FIG. 28, an upper portion of the substrate 500 exposed by the opening 525 may be doped with impurities, e.g., n-type impurities to form an impurity region 560. The impurity region 560 may serve as a common source line (CSL). In some example embodiments, a metal silicide pattern 565 may be further formed on the impurity region 560 to reduce resistance of the CSL.

Referring to FIG. 29, an insulation layer may be formed to sufficiently fill the opening 525. An upper portion of the insulation layer may be planarized to form a second insulation layer pattern 570 in the opening 525. An upper insulating interlayer 575 may be formed on the semiconductor pattern 515, the first insulation layer pattern 520, the second insulation layer pattern 570 and the uppermost insulating interlayer pattern 535d. A bit line contact 580 may be formed through the upper insulating interlayer 575 to contact the semiconductor pattern 515. A bit line 585 electrically connected to the bit line contact 580 may be formed on the upper insulating interlayer 575. The bit line 585 may have a linear shape extending in the first direction. A plurality of the bit lines 585 may be formed along the second direction. The bit line contact 580 and the bit line 585 may be formed using a metal, a metal nitride, doped polysilicon, etc.

As described above, the vertical memory device including a semiconductor pattern or a channel having high aspect ratio may be obtained using the method of forming a pattern according to example embodiments.

The hard mask layer and the method of forming a pattern according to example embodiments may also be utilized for manufacturing various semiconductor devices other than the DRAM device or the vertical memory device discussed above. For example, the hard mask layer and the method of forming a pattern may be utilized for forming a gate structure or a bit line contact of a flash memory device, or forming a conductive pattern such as a diode of a phase change random access memory (PRAM) device.

By way of summation and review, as semiconductor devices become highly integrated, patterns having a high aspect ratio are being developed. Thus, a hard mask layer having a low light absorbance and an excellent durability with respect to an etching process is desirable. If an amorphous carbon layer (ACL) formed by a low temperature process is used as a hard mask layer in an etching process, the ACL may have a low durability in the etching process due to a poor etching selectivity. If an ACL formed by a high temperature process is used, the ACL may have a high light absorbance, resulting in a low transparency.

Embodiments described herein advance the art by providing methods of forming a carbon type hard mask layer using induced coupled plasma, thereby providing a carbon type hard mask layer that may have a high etching selectivity and a high transparency. In particular, according to example embodiments, induced coupled plasma may be utilized to maintain a high plasma density, so that a carbon type hard mask layer may be rapidly formed. A crystallinity of the carbon type hard mask layer may be controlled by adjusting a bias power so that a diamond-like carbon layer having a great carbon density and a high transparency may be obtained, even by a low temperature process. Patterns having a high aspect ratio in various semiconductor devices may be formed using the diamond-like carbon layer as an etching mask.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A method of forming a carbon type hard mask layer using induced coupled plasma, the method comprising:
loading a substrate onto a lower electrode in a process chamber of an induced coupled plasma (ICP) deposition apparatus, the process chamber including an upper electrode and the lower electrode therein;
generating a plasma in the process chamber;
injecting a reactive gas into the process chamber such that the reactive gas is activated by colliding with the plasma, the reactive gas including a hydrocarbon compound gas; and
applying a bias power to the lower electrode to form a diamond-like carbon layer on the substrate from the activated reactive gas.

2. The method as claimed in claim 1, wherein the bias power applied to the lower electrode is from about 500 W to about 2000 W.

3. The method as claimed in claim 2, wherein the bias power applied to the lower electrode is from about 900 W to about 1100 W.

4. The method as claimed in claim 1, wherein the hydrocarbon compound gas includes at least one of C₃H₆, C₄H₈ and C₆H₁₂.

5. The method as claimed in claim 1, wherein the diamond-like carbon layer has an absorption coefficient in a range of from about 0.05 to about 0.09.

6. The method as claimed in claim 1, wherein the diamond-like carbon layer has a carbon density in a range of from about 1.4 g/cc to about 1.7 g/cc.

7. The method as claimed in claim 1, wherein the substrate is maintained at a temperature of from about 75° C. to about 300° C.

8. The method as claimed in claim 1, wherein the reactive gas further includes a boron-containing gas.

9. The method as claimed in claim 8, wherein the boron-containing gas includes at least one of borane (BH₃), diborane (B₂H₆) and boron trifluoride (BF₃).

10. The method as claimed in claim 8, wherein the reactive gas further includes hydrogen gas.

11. The method as claimed in claim 1, wherein:
the ICP deposition apparatus further includes a gas supply providing the reactive gas and a process gas for generating the plasma, and
the gas supply includes a top nozzle and a side nozzle disposed at an upper wall and a sidewall of the process chamber, respectively.

12. The method as claimed in claim 11, wherein the reactive gas is provided into the process chamber through the top nozzle at a flow rate of about 5 sccm to about 15 sccm and through the side nozzle at a flow rate of about 160 sccm to about 200 sccm.

13. The method as claimed in claim 12, wherein:
the reactive gas further includes a boron-containing gas, and
the boron-containing gas is provided into the process chamber through the side nozzle at a flow rate of about 10 sccm to about 70 sccm.

14. A method of forming a pattern, the method comprising:
loading a substrate having an insulation layer thereon onto a lower electrode in a process chamber of an induced coupled plasma (ICP) deposition apparatus;
generating a plasma in the process chamber;
injecting a reactive gas into the process chamber such that the reactive gas is activated by colliding with the plasma, the reactive gas including a hydrocarbon compound gas;
applying a bias power to the lower electrode to form a hard mask layer on the insulation layer from the activated reactive gas, the hard mask layer including a diamond-like carbon;
etching the hard mask layer to form a hard mask layer pattern; and
etching the insulation layer to form an insulation layer pattern using the hard mask layer pattern as an etching mask.

15. The method as claimed in claim 14, wherein the reactive gas further includes a boron-containing gas.

16. A method of patterning one or more etching-subject layers stacked on a substrate, the method comprising:
loading a substrate having the one or more etching-subject layers stacked thereon onto a lower electrode in a process chamber of an induced coupled plasma (ICP) deposition apparatus;
generating a plasma in the process chamber;
injecting a reactive gas into the process chamber such that the reactive gas is activated by colliding with the plasma, the reactive gas including a hydrocarbon compound gas and a boron-containing compound;
applying a bias power to the lower electrode to form a hard mask layer on the exposed surfaces of the one or more etching-subject layers, thereby forming a hard mask layer including a diamond-like carbon layer on the exposed surfaces of the one or more etching-subject layers;
etching the hard mask layer to form a hard mask layer pattern; and
patterning the one or more etching-subject layers by etching, using the hard mask layer pattern as an etching mask.

17. The method as claimed in claim 16, wherein the reactive gas further includes hydrogen gas.

18. The method as claimed in claim 16, wherein the bias power is applied to the electrode in a range of about 500 W to about 2000 W, and the substrate is maintained at a temperature of from about 75° C. to about 300° C. during the forming of the hard mask layer.

19. The method as claimed in claim 16, wherein:
the ICP deposition apparatus further includes a gas supply providing the reactive gas and a process gas for generating the plasma, and
the gas supply includes a top nozzle and a side nozzle disposed at an upper wall and a sidewall of the process chamber, respectively,
the hydrocarbon gas is provided into the process chamber through the top nozzle at a flow rate of about 5 sccm to about 15 sccm and through the side nozzle at a flow rate of about 160 sccm to about 200 sccm, and
the boron-containing gas is provided into the process chamber through the side nozzle at a flow rate of about 10 sccm to about 70 sccm.
